(19) United States
(12) Patent Application Publication
(10) Pub. No.: US 2021/0165211 A1
(43) Pub. Date: Jun. 3, 2021

(54) MICROMECHANICAL COMPONENT AND MANUFACTURING METHOD FOR A MICROMECHANICAL COMPONENT

(71) Applicant: Robert Bosch GmbH, Stuttgart (DE)

(72) Inventor: Frank Schatz, Kornwestheim (DE)

(21) Appl. No.: 17/083,227

(22) Filed: Oct. 28, 2020

(30) Foreign Application Priority Data
Nov. 28, 2019 (DE) 102019218468.5

(51) Int. Cl. G02B 26/08; H01L 41/09; G02B 26/10

(52) U.S. Cl. CPC G02B 26/0858; G02B 26/105; H01L 41/09

(57) ABSTRACT

A micromechanical component including a mount, an adjustable part, and a meander-shaped spring. An outer end of the meander-shaped spring is attached to the mount and an inner end of the meander-shaped spring is attached to the adjustable part. An actuator device is formed at an outer surface of and/or in the meander-shaped spring in such a way that, using the actuator device, periodic deformations of the meander-shaped spring are excitable, by which the adjustable part is adjustable in relation to the mount around a rotational axis. The component includes a torsion spring which is situated on a side opposite to the meander-shaped spring and extends along the rotational axis and is attached at an outer end of the torsion spring to the mount and at an inner end of the torsion spring to the adjustable part. The meander-shaped spring is situated in sections on the rotational axis.

### CROSS REFERENCE

The present application claims the benefit under 35 U.S.C. § 119 of German Patent Application No. DE 102019218468.5 filed on Nov. 28, 2019, which is expressly incorporated herein by reference in its entirety.

### FIELD

The present invention relates to a micromechanical component. The present invention also relates to a manufacturing method for a micromechanical component.

### BACKGROUND INFORMATION

An adjustable micromirror is described in Japan Patent Application No. JP 2009-223165 A, which is to be adjustable with the aid of two meander-shaped springs having sections that are each covered by at least one piezoelectric material, in relation to a mount of the adjustable micromirror. In particular, alternately a bending stress or a tensile stress is to be able to be formed on the sections of the two meander-shaped springs by applying at least one voltage to the at least one piezoelectric material in such a way that the adjustable micromirror is adjusted in relation to its mount with the aid of an effectuated mirror-symmetrical deformation of the two meander-shaped springs.

An object of the present invention is to provide a simplified micromechanical component.

### SUMMARY

In accordance with an example embodiment of the present invention, a micromechanical component including a mount, an adjustable part, and a meander-shaped spring is provided. The meander-shaped spring is attached in this case at an outer end of the meander-shaped spring directly or indirectly to the mount and at an inner end of the meander-shaped spring directly or indirectly to the adjustable part. An actuator device is formed on an outer surface of the meander-shaped spring and/or in the meander-shaped spring in such a way that periodic deformations of the meander-shaped spring are excitable with the aid of the actuator device, by which the adjustable part is adjustable in relation to the mount around a rotational axis of the adjustable part. In addition, the mechanical component includes a torsion spring. This torsion spring is situated on a side opposite to the meander-shaped spring with respect to a plane which is situated perpendicularly to the rotational axis of the adjustable part. The rotational axis is thus essentially orthogonal to this plane. This plane corresponds in particular to a plane of symmetry of the adjustable part, in particular a micromirror. The torsion spring extends at least in sections along the rotational axis and is attached at an outer end of the torsion spring directly or indirectly to the mount and at an inner end of the torsion spring directly or indirectly to the adjustable part. The meander-shaped spring which is located on the other side of the plane is situated in sections on the rotational axis.

The drive of the adjustable part is thus provided by only one single meandering drive. A passive torsion spring, which is used for suspending the adjustable part at the mount, is situated opposite to the meandering drive. The deflection of the adjustable part may be determined easily by this torsion spring, since in a torsion spring without drive, the deflection angle is proportional to the load measured at the torsion spring. A further advantage of this mechanical component is that the torsion spring requires less space than a second meandering drive. Space may thus be saved.

The meander-shaped spring preferably extends in sections along the rotational axis. A relatively symmetrical suspension of the adjustable part at the mount thus results.

An extension of the meander-shaped spring in the direction of an axis essentially perpendicular to the rotational axis preferably corresponds to at least 50% of an extension of the adjustable part in the direction of the axis essentially perpendicular to the rotational axis. The axis essentially perpendicular to the rotational axis is in particular a transverse axis of the adjustable part, in particular a micromirror. Since the micromechanical component only has one single meandering drive on one side of the adjustable part, this meandering drive may be designed to be wider and a greater deflection angle of the adjustable part may thus be achieved upon deflection. The extension of the meander-shaped spring in the direction of the axis essentially perpendicular to the rotational axis preferably corresponds to the extension of the adjustable part in the direction of the axis essentially perpendicular to the rotational axis. The meandering drive thus uses the full width of the micromirror. The greatest possible deflection angle of the adjustable part may thus be achieved by only one single meandering drive.

The meander-shaped spring is preferably attached centrally in the rotational axis of the adjustable part directly or indirectly at the adjustable part. A symmetrical suspension of the adjustable part at the mount thus results.

The adjustable part is preferably designed as a micromirror. The mirror surface of the micromirror is in particular formed rectangular or circular here. The micromirror or its mirror surface thus has two planes of symmetry situated perpendicularly to one another.

The torsion spring preferably has a height and a width, the height of the torsion spring being designed to be greater than the width of the torsion spring. In particular, a dimension of the height in relation to a dimension of the width of the torsion spring corresponds at least to a ratio of 1.2:1. A comparatively tall and narrow torsion spring thus results, which is designed to be comparatively soft with respect to the torsion deformation. The meandering drive thus does not have to exert a large force to deflect the torsion spring. A large deflection angle of the adjustable part may thus in turn be maintained. However, a torsion spring designed in this way is designed to be comparatively rigid in the z direction. The z mode, also called the stroke mode, is shifted toward higher frequencies by this torsion spring which is rigid in the z direction, which is accompanied by advantages for the control of the adjustable part, in particular the micromirror.

The torsion spring is preferably designed as a meandering torsion spring. This saves space in relation to a linear torsion spring and the micromechanical component may thus be designed to be smaller as a whole.

The micromechanical component preferably includes at least one sensor device, which is designed to output or provide at least one sensor signal corresponding to a deflection of the adjustable part from its idle position in relation to the mount. The sensor device is connected via at least one signal line formed on an outer surface of the torsion spring and/or in the torsion spring to evaluation electronics formed on the mount or an evaluation electronics connection contact formed on the outer surface of the mount. For electrical contacting of the sensor device, a signal line formed on the outer surface and/or in the at least two meander-shaped springs according to the related art may thus be omitted. The electrical contacting of the sensor device is thus not linked to any secondary effects with regard to a desired good flexibility of the meander-shaped springs. Alternatively, the sensor device is preferably situated at the outer end of the torsion spring and is connected via at least one signal line formed on an outer surface of the mount and/or in the mount to evaluation electronics formed on the mount or an evaluation electronics connection contact formed on the outer surface of the mount. Leading the signal line via the torsion spring may thus also be omitted.

The actuator device preferably includes at least one piezoelectric actuator layer made of at least one piezoelectric material, which is formed on the outer surface and/or in multiple sections of the associated meander-shaped spring. The actuator device additionally includes at least one electrical line, which is formed on the outer surface and/or in the meander-shaped spring in such a way that at least one voltage signal is applicable to the piezoelectric actuator layer of the meander-shaped spring in such a way that the periodic deformations of the meander-shaped spring may be effectuated. In this way, the sections of the meander-shaped spring formed having the piezoelectric actuator layer may be bent so that the adjustable part is adjusted by a relatively high adjustment angle out of its idle position in relation to the mount around the rotational axis.

The above-described advantages are also provided when a corresponding manufacturing method is carried out for such a micromechanical component. It is to be expressly noted that the manufacturing method may be refined in such a way that all above-explained micromechanical components may be manufactured thereby.

### BRIEF DESCRIPTION OF THE DRAWINGS

FIG. 1a shows a first specific embodiment of a micromechanical component in accordance with the present invention.

FIG. 1b shows a second specific embodiment of a micromechanical component in accordance with the present invention.

FIG. 1c shows a third specific embodiment of a micromechanical component in accordance with the present invention.

FIG. 2 shows a sequence of a manufacturing method for a micromechanical component in accordance with the present invention.

### DETAILED DESCRIPTION OF EXAMPLE EMBODIMENTS

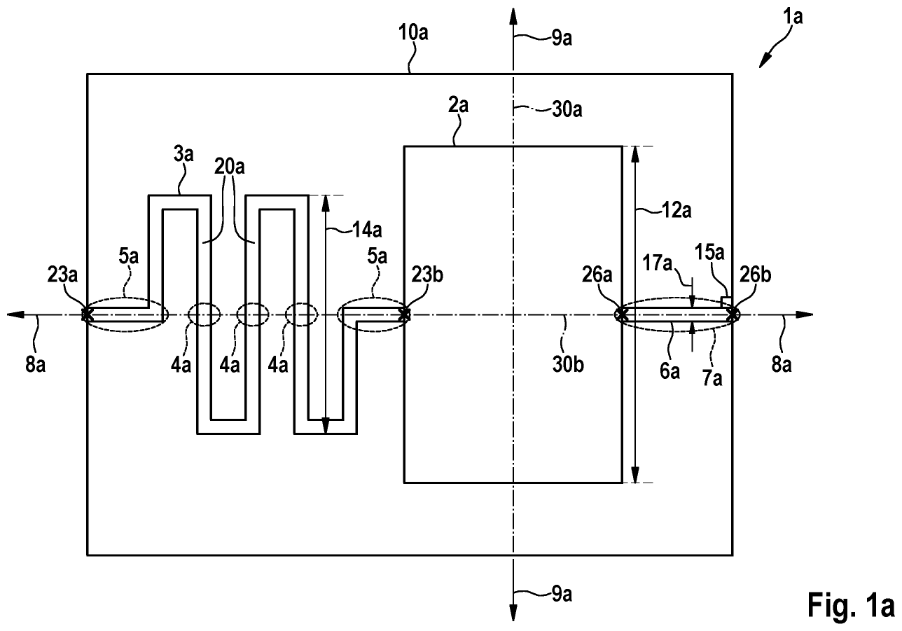

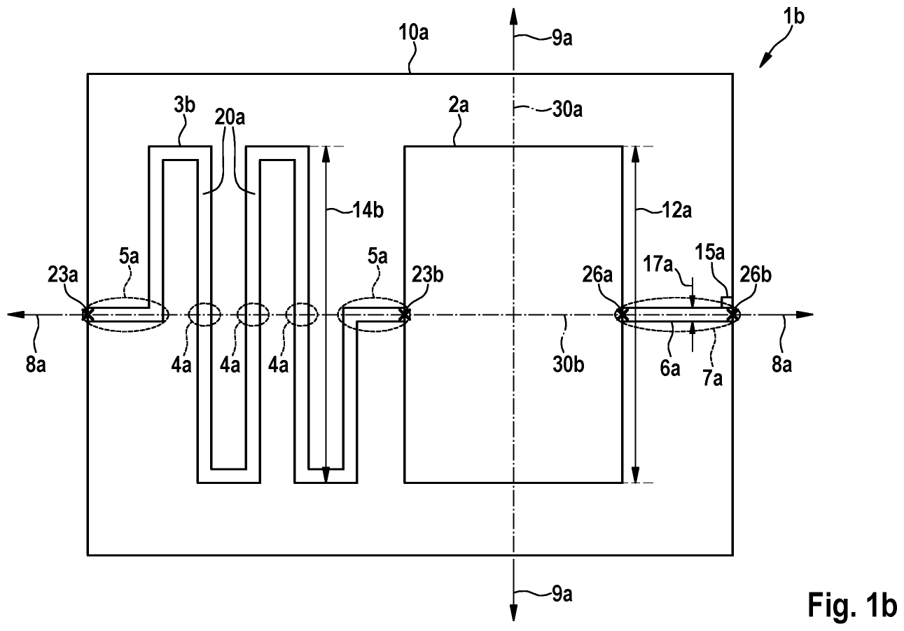

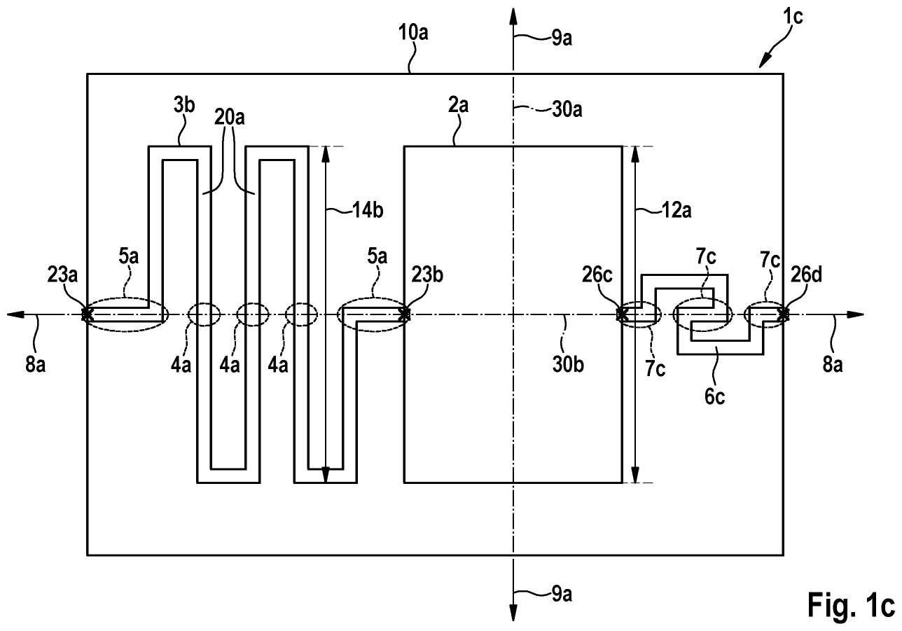

FIG. 1a shows a schematic overall representation of a first specific embodiment of micromechanical component 1a. Micromechanical component 1a includes a mount 10a, an adjustable part 2a, and a meander-shaped spring 3a. Meander-shaped spring 3a is attached here at an outer end 23a of meander-shaped spring 3a directly to mount 10a and at an inner end 23b of meander-shaped spring 3a directly to adjustable part 2a. In this first exemplary embodiment, meander-shaped spring 3a is attached at inner end 23b of meander-shaped spring 3a centrally in rotational axis 30b of adjustable part 2a directly to adjustable part 2a. An actuator device 20a and 20b in the form of a piezoelectric layer is formed in meander-shaped spring 3a in such a way that periodic deformations of meander-shaped spring 3a are excitable with the aid of actuator device 20a and 20b, by which adjustable part 2a is adjustable in relation to mount 10a around a rotational axis 30b of adjustable part 2a. In addition, mechanical component 1a includes a torsion spring 6a. This torsion spring 6a is formed here as a linear torsion spring. The torsion spring is situated on a side opposite to meander-shaped spring 3a with respect to a plane 9a, which is situated essentially perpendicularly to rotational axis 30b of adjustable part 2a. Rotational axis 30b is thus essentially orthogonal to this plane. Adjustable part 2a is designed here by way of example as a micromirror having a rectangular mirror surface. Adjustable part 2a thus has two planes of symmetry situated perpendicularly to one another in this specific embodiment. Plane 9a situated perpendicularly to rotational axis 30b of adjustable part 2a corresponds in this context to a first plane of symmetry of adjustable part 2a. Rotational axis 30b extends in the direction of second plane of symmetry 8a of adjustable part 2a.

Torsion spring 6a extends in this exemplary embodiment in section 7a completely along rotational axis 30b and is attached at an outer end 26b directly to mount 10a. At an inner end of torsion spring 6a, torsion spring 6a is directly attached to adjustable part 2a. On the one hand, torsion spring 6a contributes to stabilizing the desired rotational movement of adjustable part 2a around rotational axis 30b. In particular, torsion spring 6a increases a rigidity of micromechanical component 1a in relation to an undesired adjustment movement of adjustable part 2a in an axis 30a aligned perpendicularly to rotational axis 30b. On the other hand, the deflection of the adjustable part may also be determined easily via torsion spring 6a, since in a torsion spring without drive, the deflection angle is proportional to the load measured at the torsion spring.

In contrast, meander-shaped spring 3a, which is located on the other side of plane 9a, is only situated in sections 4a, 23a, and 23b on rotational axis 30b. While meander-shaped spring 3a only intersects rotational axis 30b in sections 4a, meander-shaped spring 3a extends in sections 23a and 23b along rotational axis 30b.

Due to the meandering shape, meander-shaped spring 3a may be made comparatively long without the individual length of meander-shaped spring 3a contributing to a significant enlargement of micromechanical component 1a. An individual length of meander-shaped spring 3a may be, for example, greater than or equal to 200 μm, in particular greater than or equal to 500 μm, especially greater than or equal to 1 mm (millimeter).

In the example of FIG. 1, actuator device 20a and 20b includes in each case at least one piezoelectric actuator layer (not shown here) made of at least one piezoelectric material. The piezoelectric material may be, for example, PZT. The piezoelectric actuator layer may have, for example, a layer thickness between 0.5 μm (micrometer) and 2 μm (micrometer). For the interaction with the piezoelectric actuator layer, actuator device 20a and 20b also has at least one electrical line (not shown), which is formed at an outer surface and/or in meander-shaped spring 3a. Therefore, at least one voltage signal may be applied to the piezoelectric actuator layer in such a way that at least the periodic deformations of meander-shaped spring 3a may be effectuated/are effectuated. Such a design of actuator device 20a and 20b as a piezoelectric actuator device is distinguished by high adjustment forces, but only low positioning distances. An adjustment of adjustable part 2a around rotational axis 30b with the aid of piezoelectric actuator devices 20a and 20b described here preferably does not take place in a resonant manner. If voltage is not applied to the piezoelectric actuator layer, adjustable part 2a is thus provided in its so-called idle position in relation to mount 10a.

As an advantageous refinement of the present invention, the micromechanical component may also include at least one sensor device 15a, which is designed to output or provide at least one sensor signal corresponding to a deflection of adjustable part 2a out of its idle position in relation to mount 10a. Sensor device 15a may be, for example, a piezoelectric or piezoresistive sensor device 15a. In this exemplary embodiment, sensor device 15a is formed on an “anchoring area” of torsion spring 6a at mount 10a. The formation of sensor device 15a at the outer end of torsion spring 6a enables an unambiguous detection/recognition of a deflection of adjustable part 2a out of its idle position around rotational axis 30b in relation to mount 10a. In particular, such a design of sensor device 15a is more advantageous than the conventional positioning of a sensor at one of meander-shaped springs 3a, which often does not permit reliable correlation to the deflection of adjustable part 2a and furthermore results in the disadvantage that interference modes of micromechanical component 1a are incorrectly indicated as the desired deflection of adjustable part 2a out of its idle position around rotational axis 30b.

Sensor device 15a is advantageously additionally connected via at least one signal line (not shown) formed at the outer surface of mount 10a to evaluation electronics formed on mount 10a or an evaluation electronics connection contact formed on mount 10a. Forming the at least one signal line at the outer surface and/or in meander-shaped spring 3a may thus be omitted without problems. A bending rigidity of meander-shaped spring 3a is thus not negatively affected by the signal line guided via torsion spring 6a. Furthermore, the signal line is not influenced by the convex/concave bending of meander-shaped spring 3a nor do the electrical signals interfere with the actuator and sensor signal line.

In this first specific embodiment of the present invention, meander-shaped spring 3a has an extension 14a in the direction of an axis 30a essentially perpendicular to rotational axis 30b, which is at least 50% of an extension 12a of adjustable part 2a in the direction of axis 30a essentially perpendicular to rotational axis 30b. The extension of meander-shaped spring 3a is in this case a length of the bent spring sections in the corresponding direction. The extension of adjustable part 2a is in this context a width of adjustable part 2a.

Torsion spring 6a has in this case a height (not shown in this illustration) and a width 17a. The height of the torsion spring is greater than width 17a of torsion spring 6a.

FIG. 1b shows a schematic overall illustration of a second specific embodiment of micromechanical component 1b, in accordance with the present invention.

In this case, in contrast to the first specific embodiment, extension 14b of meander-shaped spring 3b in the direction of axis 30a essentially perpendicular to rotational axis 30b corresponds to extension 12a of adjustable part 2a in the direction of axis 30a essentially perpendicular to rotational axis 30b. The maximum deflection angle of adjustable part 2a is thus achieved.

FIG. 1c shows a schematic overall illustration of a third specific embodiment of micromechanical component 1c, in accordance with the present invention.

In contrast to the second specific embodiment, torsion spring 6c is formed as a meandering torsion spring in this case. Meandering torsion spring 6c extends on sections 7c on rotational axis 30b and is attached at an outer end 26d of torsion spring 6c directly to mount 2a and at an inner end 26c of torsion spring 6c directly to adjustable part 2a.

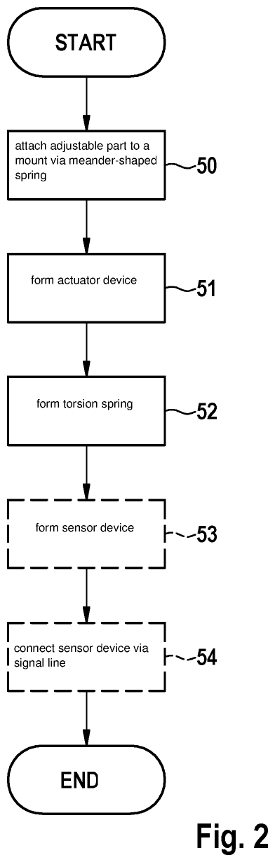

FIG. 2 shows a flowchart to explain one specific embodiment of the manufacturing method, in accordance with the present invention.

All above-described micromechanical components may be manufactured with the aid of the manufacturing method described hereinafter. However, a feasibility of the manufacturing method is not restricted to the manufacturing of the above-described micromechanical components.

Attaching an adjustable part to a mount via at least one meander-shaped spring, which is situated sectionally on a rotational axis of the adjustable part, an outer end of the meander-shaped spring being attached directly or indirectly to the mount and an inner end of the meander-shaped spring being attached directly or indirectly to the adjustable part; and forming an actuator device at an outer surface of the meander-shaped spring and/or in the meander-shaped spring in such a way that during operation of the later micromechanical component with the aid of the actuator device, periodic deformations of the meander-shaped spring are excited, by which the adjustable part is adjusted in relation to the mount around the rotational axis of the adjustable part;

characterized by the step:

forming a torsion spring, which extends at least sectionally along the rotational axis of the adjustable part, where an outer end of the torsion spring is attached directly or indirectly to the mount and an inner end of the torsion spring is attached directly or indirectly to the adjustable part in such a way that the adjustable part is adjusted with the aid of at least the periodic deformations of the meander-shaped spring in relation to the mount around the rotational axis.

In a method step 50, an adjustable part is attached to a mount via at least one meander-shaped spring. The meander-shaped spring is situated for this purpose in sections on a rotational axis of the adjustable part. An outer end of the meander-shaped spring is attached directly or indirectly to the mount and an inner end of the meander-shaped spring is attached directly or indirectly to the adjustable part. In a following method step 51, an actuator device is formed at an outer surface of the meander-shaped spring and/or in the meander-shaped spring in such a way that during operation of the later micromechanical component with the aid of the actuator device, periodic deformations of the meander-shaped spring are excited. The adjustable part is adjusted in relation to the mount by these excited periodic deformations.

In a following method step 52, a torsion spring is formed, which extends at least in sections along the rotational axis of the adjustable part. An outer end of the torsion spring is attached directly or indirectly to the mount and an inner end of the torsion spring is attached directly or indirectly to the adjustable part. This has the effect that the adjustable part is adjusted with the aid of at least the periodic deformations of the meander-shaped spring in relation to the mount around the rotational axis. The manufacturing method described here thus also effectuates the above-described advantages. To carry out method steps 50 and 52, the particular components may be structured, for example, out of monocrystalline, polycrystalline, or epi-polycrystalline silicon, especially out of a silicon layer of an SOI substrate (silicon-on-insulator substrate).

As an optional refinement, the manufacturing method may also include method steps 53 and 54. In method step 53, a sensor device is formed for providing or outputting at least one sensor signal corresponding to a deflection of the adjustable part out of its idle position in relation to the mount. In method step 54, the sensor device is connected via at least one signal line formed at an outer surface of the torsion spring and/or in the torsion spring to evaluation electronics formed on the mount or an evaluation electronics connection contact formed on the mount. Alternatively to this step, the sensor device is connected via at least one signal line formed on an outer surface of the mount and/or in the mount to evaluation electronics formed at the mount or an evaluation electronics connection contact formed on the mount. Further components of the above-described micromechanical components may also be formed with the aid of corresponding method steps. The above-described micromechanical components are technologically implementable in a simple manner.

Method steps 50 through 54 may be carried out in any sequence, overlapping in time, or simultaneously.

What is claimed is:

1. A micromechanical component, comprising:
a mount;
an adjustable part;
a meander-shaped spring which is attached at an outer end of the meander-shaped spring directly or indirectly to the mount and at an inner end of the meander-shaped spring directly or indirectly to the adjustable part;
an actuator device formed at an outer surface of the meander-shaped spring and/or in the meander-shaped spring, in such a way that, using the actuator device, periodic deformations of the meander-shaped spring are excitable, whereby the adjustable part is adjustable in relation to the mount around a rotational axis; and
a torsion spring which is situated, with respect to a plane perpendicular to the rotational axis of the adjustable part, on a side opposite to the meander-shaped spring and extends at least sectionally along the rotational axis, and is attached at an outer end of the torsion spring directly or indirectly to the mount, and at an inner end of the torsion spring directly or indirectly to the adjustable part;
wherein the meander-shaped spring is situated sectionally on the rotational axis.

2. The micromechanical component as recited in claim 1, wherein the meander-shaped spring extends sectionally along the rotational axis.

3. The micromechanical component as recited in claim 1, wherein an extension of the meander-shaped spring, in a direction of an axis perpendicular to the rotational axis, corresponds to at least 50% of an extension of the adjustable part in the direction of the axis perpendicular to the rotational axis.

4. The micromechanical component as recited in claim 3, wherein the extension of the meander-shaped spring in the direction of the axis perpendicular to the rotational axis corresponds to the extension of the adjustable part in the direction of the axis perpendicular to the rotational axis.

5. The micromechanical component as recited in claim 1, wherein the meander-shaped spring is attached centrally in the rotational axis of the adjustable part directly or indirectly to the adjustable part.

6. The micromechanical component as recited in claim 1, wherein the adjustable part is a micromirror, which is rectangular or circular.

7. The micromechanical component as recited in claim 1, wherein the torsion spring has a height and a width, the height of the torsion spring is greater than the width of the torsion spring.

8. The micromechanical component as recited in claim 1, wherein the torsion spring is a meander-shaped torsion spring.

9. The micromechanical component as recited in claim 1, wherein the micromechanical component includes at least one sensor device which is configured to output or provide at least one sensor signal corresponding to a deflection of the adjustable part out of its idle position in relation to the mount, and the sensor device is connected via at least one signal line formed at an outer surface of the mount and/or in the mount to: (i) evaluation electronics formed on the mount or (ii) an evaluation electronics connection contact formed at the outer surface of the mount.

10. The micromechanical component as recited in claim 1, wherein the actuator device includes at least one piezoelectric actuator layer made of at least one piezoelectric material, which is formed at the outer surface of and/or in multiple sections of the associated meander-shaped spring, and at least one electrical line, which is formed at the outer surface of and/or in the meander-shaped spring, in such a way that at least one voltage signal is applicable to the piezoelectric actuator layer of the meander-shaped spring in such a way that the periodic deformations of the meander-shaped spring are effectuated.

11. A manufacturing method for a micromechanical component, comprising the following steps:
attaching an adjustable part to a mount via at least one meander-shaped spring, which is situated in sections on a rotational axis of the adjustable part, an outer end of the meander-shaped spring being directly or indirectly attached to the mount and an inner end of the meander-shaped spring being directly or indirectly attached to the adjustable part;
forming an actuator device, at an outer surface of the meander-shaped spring and/or in the meander-shaped spring, in such a way that during operation of the manufactured micromechanical component, using the actuator device, periodic deformations of the meander-shaped spring are excited, by which the adjustable part is adjusted in relation to the mount around the rotational axis of the adjustable part; and
forming a torsion spring which extends at least in sections along the rotational axis of the adjustable part, an outer end of the torsion spring being attached directly or indirectly to the mount and an inner end of the torsion spring being attached directly or indirectly to the adjustable part in such a way that the adjustable part is adjusted using at least the periodic deformations of the meander-shaped spring in relation to the mount around the rotational axis.

12. The manufacturing method as recited in claim 11, further comprising the following steps:
forming a sensor device configured to providing or output at least one sensor signal corresponding to a deflection of the adjustable part out of its idle position in relation to the mount; and
connecting the sensor device via at least one signal line formed at an outer surface of the mount and/or in the mount to: (i) evaluation electronics formed on the mount, or (ii) an evaluation electronics connection contact formed on the mount.
